(19) United States
(12) Patent Application Publication
(10) Pub. No.: US 2007/0032072 A1
(43) Pub. Date: Feb. 8, 2007

(54) Nucleation layer deposition on semiconductor process equipment parts

(75) Inventor: Ardeshir J. Sidhwa, Scottsdale, AZ (US)

Correspondence Address: STMICROELECTRONICS, INC., MAIL STATION 2346, 1310 ELECTRONICS DRIVE, CARROLLTON, TX, 75006, US

(73) Assignee: STMicroelectronics Inc., Carrollton, TX (US)

(21) Appl. No.: 11/194,921

(22) Filed: Aug. 2, 2005

(51) Int. Cl. H01L 21/44

(52) U.S. Cl. 438/653

(57) ABSTRACT

A plasma chamber is provided having an upper insulating member as a lid of the plasma chamber. The lid of the plasma chamber, usually in the form of a bell jar, has an inside surface which will be exposed to the interior of the plasma chamber. A nucleation layer is affixed to the inside surface of the insulating member. The nucleation layer is selected to be a material which will enhance the growth on itself of the particular material being etched within the process chamber. For example, if the pre-clean chamber is being used to etch oxides, the nucleation layer is selected to be of a type which will create a large number of nucleation sites for the growth of an oxide layer on the interior wall of the bell jar. Each nucleation site becomes the starting point for the adherence of the etched oxide atoms onto the wall of the bell jar. Wafers pre-cleaned in such a chamber have a lower defect density. Further, longer times are permitted between cleaning and replacing components in the pre-clean chamber.

### BACKGROUND OF THE INVENTION

1. Field of the Invention

This invention is related to the manufacturing of semiconductor products, and more particularly to a machine for the manufacture of integrated circuit chips.

2. Description of the Related Art

The processing of integrated circuit chips occurs in a number of different steps. The steps are often carried out in different etch chambers, others are carried out in furnaces, while others of which are deposition or implantation chambers. The semiconductor wafer frequently moves from one chamber to another as part of the integrated circuit fabrication process.

One of the process chambers frequently used as the wafer is moved from station to station is a pre-clean chamber. The pre-clean chamber is used to clean or etch material from a substrate to prepare it for the next stage by various techniques, including sputter etching, plasma etching, or the like. The etching may, for example remove portions of a top layer in order to expose a lower layer to form a conductive pattern. It may remove all or part of a dielectric layer, an oxide protective layer or some other layer as part of the process of producing the final integrated circuit.

A frequent use of the pre-clean chamber is the removal of a previous level oxide layer or native oxide which grows incidentally on the topmost layer on the integrated circuit. Whenever a wafer is exposed to an atmosphere which contains oxygen, it is common for a layer of oxide, of various thickness, to adhere to the exposed surface. It is usually desirable to remove this layer completely after one step before proceeding with the next step. For example, a metal layer present on the chip may have a thin oxide layer on the upper surface of the metal layer. It is desirable to remove the oxide layer completely prior to a subsequent deposition step so that good electrical contact is obtained between the metal layer and subsequent conductive layers in contact with that metal layer. Therefore, it is desirable to perform a cleaning in the form of an etch of the oxide layer before proceeding with the next step.

During such etching or cleaning of the substrate, the material that is etched from the wafer may redeposit at a different location on the same or other wafers. This will reduce the overall conductivity of the layer or, in a worst case scenario cause defects in the formation of the integrated circuit components. It is known in the art that some of the material etched from the substrate may deposit on the walls of the enclosure within which the etching takes place. Unfortunately, such deposits may flake off at various times which are unpredictable. For example, they may fall off while a wafer is being removed or placed into the process chamber and contaminate the wafer.

One prior art solution has been proposed in U.S. Pat. No. 6,777,045 (the '045 patent), incorporated by reference herein. According to the teachings of the '045 patent, it is proposed to provide a roughened surface of the interior portion of a domed enclosure wall, such as a bell jar. By roughening the surface of the bell jar, it is hoped that the material which has been etched will stick to the roughened, textured surface and provide good long term adherence. A ceramic layer is then deposited on the roughened bell jar surface to provide on even more textured or rough surface to promote the adherence of the etch material. According to the '045 patent, the adherence is obtained by having a high degree of roughness of the surface so as to create a highly textured surface. While such a roughened surface may provide some improvement over some prior techniques, it still has shortcomings related to providing long term, low cost solutions to the defects which may be caused based on flaking off of the etch material from the bell jar surface onto subsequent semiconductor substrates which were placed into the bell jar for further processing. Accordingly, an improved technique for reducing the number of defects and increasing the life of the processing chamber components is desirable.

### BRIEF SUMMARY OF THE INVENTION

According to principles of the present invention, a plasma chamber is provided having an upper insulating member as a lid of the plasma chamber. The lid of the plasma chamber, usually in the form of a bell jar, has an inside surface which will be exposed to the interior of the plasma chamber. A nucleation layer is affixed to the inside surface of the insulating member. The nucleation layer is selected to be a material which will enhance the growth on itself of the particular material being etched within the process chamber. For example, if the pre-clean chamber is being used to etch oxides, the nucleation layer is selected to be of a type which will create a large number of nucleation sites for the growth of an oxide layer on the interior wall of the bell jar. Each nucleation site becomes the starting point for the adherence of the etched oxide atoms onto the wall of the bell jar.

Having a large number of nucleation sites provides many locations where the oxide atoms may redeposit themselves and begin to grow a new layer on the inside surface of the bell jar. In addition, once the new layer begins to form at one or more nucleation sites, additional oxide atoms, will cling onto the growing layer at each nucleation site, thus forming a growing layer on the interior of the wall of the pre-clean chamber. The nucleation layer of the oxide results in growing an oxide layer on the inside wall of the plasma chamber, which can continue for long periods of time, slowly growing the layer thicker and thicker over the use of the bell jar of the pre-clean chamber. Because it is a grown layer that is attaching to existing molecules fixed to the wall of the bell jar, the layer will have very strong adhesion to the interior wall of the insulating member, and in addition will have very good adhesion to itself. Flaking is greatly reduced due to the nucleation sites and that defects due to the material just etched falling onto the semiconductor substrate at the wrong place is reduced greatly, nearly to zero.

According to one embodiment of the present invention, all material components inside the plasma chamber are coated with the nucleation layer so that the etched oxide may attach to and start to grow on numerous surfaces away from the wafer.

After a long period of time, once the layer is sufficiently large the components of the plasma chamber may be dismantled and placed in a standard cleaning solution so as to remove the grown oxide layer. This may be done by a simple wet etch, or other technique well known to remove oxide layers. The components of the plasma chamber may thereafter be used again, since the layer which has been deposited thereon has been etched by standard techniques and it is removed.

According to one embodiment of the present invention, the material for the nucleation layer is selected to be a desired foundation for the material which is to be etched so that a high number of sites will occur. For example, if oxide is the material to be etched, then the nucleation layer is made of an oxide component, preferably a combination of a metal and an oxide to provide a high affinity for the cleaned oxide. According to one preferred embodiment, zirconium oxide is used as the nucleation layer. According to another alternative embodiment, yttrium oxide or a blend between yttrium oxide and zirconium oxide is used for the nucleation layer. Of course, other particular nucleation layers may be used depending on the material to be etched. For example, the combination of elements can be selected from the periodic chart. One element from one of the period columns of IIA, IIIB, IVB may be combined with elements from columns VA or VIA. For example, selecting from column IVB, and column VA, the nucleation layer may be titanium nitride. Yttrium, a column III element may be combined with elements in columns V or VI in order to provide a nucleation layer.

The nucleation layer is applied to the interior surface of the insulating material according to techniques that are well known in the art. Preferably, the interior surface is first cleaned by bead blasting or other acceptable technique which scrubs and cleans the surface, while slightly roughening the surface to prepare it to have good adhesion to the nucleation layer. Afterwards, the nucleation layer is deposited thereon by a plasma torch. Once deposited, the entire insulating member is subjected to a heat treatment in nitrogen ambient to ensure complete out gassing and vapor removal. The heat treatment is carried out in a pure nitrogen atmosphere in order to ensure that all impurities and vapor outgases from the nucleation layer and the interior of the chamber is free of impurities prior to it being used.

### BRIEF DESCRIPTION OF THE SEVERAL VIEWS OF THE DRAWINGS

FIG. 1 is a top view of the layout of a well-known semiconductor processing unit (facility) showing use of the invention.

FIG. 2 is a cross-section view of a pre-clean chamber with a wafer present according to principles of the present invention.

FIG. 3 is an exploded view of the pre-clean chamber according to principles of the present invention.

FIG. 4 is a side elevational view of a wafer for use in the pre-clean chamber.

FIG. 5 is a graph of the improvement of the invention in defect densities as compared to the prior art.

FIGS. 6A and 6B are photographs illustrating the increased nucleation sites at high magnification using a coating according to principles of the present invention as compared to the prior art.

### DETAILED DESCRIPTION OF THE INVENTION

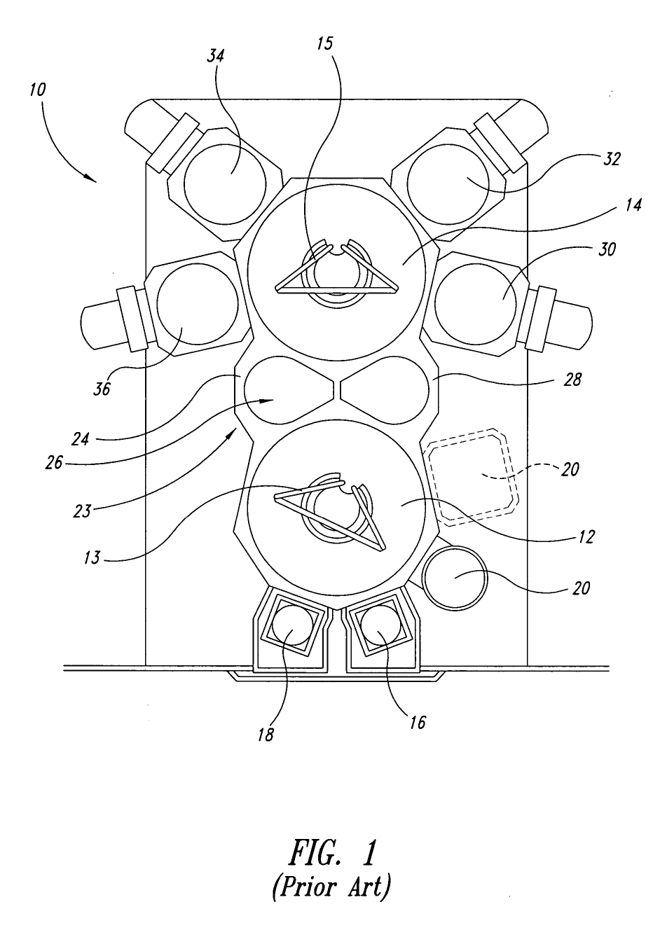

FIG. 1 is a top side view of one example of a well-known semiconductor processing facility in which the invention may be used. The processing facility 10 includes a number of chambers all of which are well known in the art, as is their operation. The facility 10 is provided as one example of the facility in which the invention may find use and, of course it may find use in other structures and facilities besides the one shown here. The example of FIG. 1 is based on the ENDURA layout, made by Applied Materials. A semiconductor processing facility 10 is available on the open market, which is well known in the art.

This particular semiconductor processing facility includes a first wafer handling chamber 12 and a second wafer handling chamber 14. The first wafer handling chamber 12 is usually used as a buffer chamber in which semiconductor wafers are prepared for further steps in the fabrication process. A robot arm 13 picks up the wafer and moves it from station to station. Various stations may be positioned around the buffer chamber 12, such as an introduction station 16 and/or 18 and an exit station as 16 and/or 18. The chambers 16 and 18 may be load lock chambers to provide a clean environment. Other chambers optionally may be provided, labeled generally as 20 which may perform various outgassing or other process steps on the semiconductor wafer as part of the manufacturing process.

The other wafer handling chamber 14 also has a robot arm 15 and is a transfer chamber which uses the robot 15 to transfer the semiconductor wafer between various manufacturing stations and furnaces. As one example, a first station 30 may be a deposition or growth chamber within which a nitride or oxide is deposited on a silicon wafer using techniques well known in the art. Other stations may include an ion implantation chamber 32, a dopant implantation deposition chamber 34, and a plasma etch chamber 36. Of course, numerous other stations may be used in the semiconductor manufacturing process, such as chambers for metal depositions, BPSG depositions, epitaxial growth and other chambers. As is well known in the art, different processes may be carried out in the same chamber by the introduction of different gasses.

The wafers are transferred between the buffer chamber 12 and the transfer chamber 14 via two intermediate chambers, a pre-clean chamber 23 and a cool-down chamber 28. The pre-clean chamber 23 has a wall 24 forming an interior 26 within which the semiconductor wafer is positioned to perform a pre-clean step prior to being moved from buffer chamber 12 to the transfer chamber 14 for additional semiconductor processing steps.

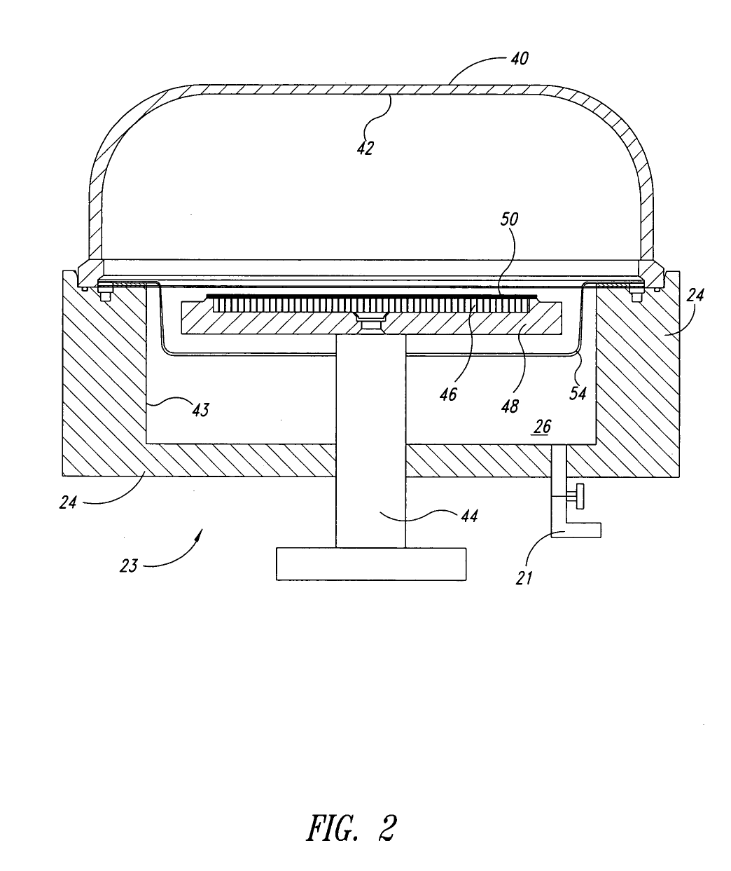

The interior 26 of the pre-clean chamber 23 is prepared according to the present invention, as will now be described with respect to FIGS. 2-5.

FIG. 2 is a cross-sectional view of the pre-clean chamber 23 having a wall 24 that defines an interior 26. The wall 24 has inside surface 43 that is exposed to gases inside the pre-clean chamber 23. Typically, the pre-clean chamber 23 has a bell jar lid 40 on the top thereof. The bell jar 40 may be made of any dielectric material such as a high quality glass, quartz, or ceramics. In a preferred embodiment, quartz is used for the bell jar 40 of the pre-clean chamber 23.

The pre-clean chamber 23 includes a number of components well known in the art. A pedestal 44 is positioned within the chamber interior 26 on which a semiconductor wafer 50 is mounted. The pedestal 44 has a chuck 48 connected in an upper end thereof in order to support the wafer 50 during the pre-clean step. The wafer 50 is supported in the well-known manner on chuck 48, for example there may be a plurality of support fingers 46 across the backside of the wafer. One or more pipes 21 are provided to permit gases to flow in or out of the preclean chamber 23 in a manner well known in the art.

The pre-clean chamber 23 is used to clean the semiconductor wafers before further processing. Typically, the semiconductor wafer will have a thin coat of oxide on the exposed surface thereof. Since oxygen is highly reactive with the surfaces of the semiconductor wafer, it is typical for a thin coating of oxide to form on, or in some cases bond with, any exposed surface of the semiconductor wafer. In some instances, this may be in the form of oxygen, oxide, or a silicon dioxide layer. In other instances, this layer may be a titanium oxide, an aluminum oxide, a tungsten oxide or some other layer formed on an exposed surface on the semiconductor wafer. In order to form good electrical contacts, it is desirable to completely clean the wafer of all oxide layers, including compounds with an oxide therein which may have formed chemically when the wafer was exposed to an atmosphere containing oxygen or from the previous process steps. As is well known in the art, in the pre-clean chamber 23 can be a plasma etch chamber which creates a plasma etch for the removal of the oxide layer on the surface of the semiconductor wafer. As oxygen is removed from the layer, it is transported briefly through the atmosphere inside the chamber 26 and may stick to any exposed surface, such as the interior surface 42 of the bell jar 40.

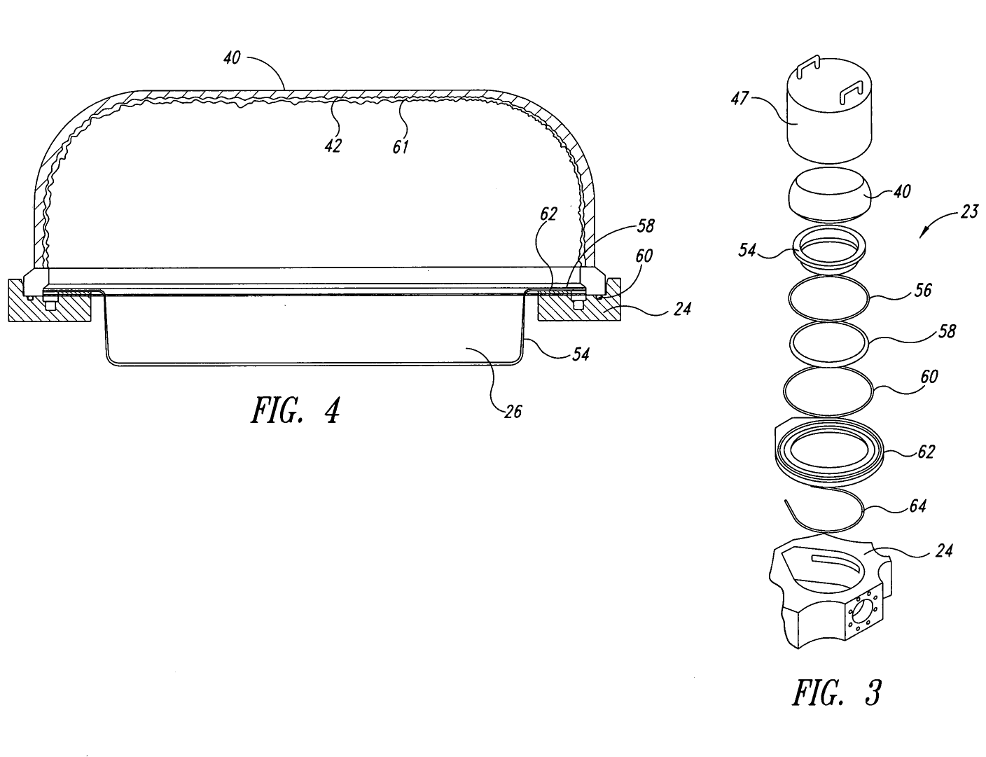

FIG. 3 shows an exploded detail of the pre-clean chamber 23. The pre-clean chamber includes a radio frequency resonator 47 which includes a magnetic shield and the appropriate power supply connection, the specific details of which are not shown since they are well known in the art. The RF resonator 47 encloses the bell jar and provides one power source for the system. The bell jar 40 has an interior surface 42 that provides the upper surface for the enclosure which forms the chamber 26. A shield 54 is inside the chamber 23 and serves as a protective shield around the semiconductor wafer 50 during the pre-clean operation. An O-ring 56, gas trench cover 58 and gasket 60 are provided to form an enclosing seal between the chamber wall 24 and the bell jar 40. An adapter 62 is also positioned within the chamber with a gasket 64. The major components as shown in FIGS. 3 and 4 are those of a standard pre-clean chamber and as individual components are known in the prior art. Therefore, further details of their connection and operation are not provided herein since any bell jar or pre-clean chamber assembly may make use of the invention as described herein.

As shown in FIG. 4, according to principles of the present invention, the interior surface 42 of the bell jar 40 is coated with a nucleation layer 61. Other components may also have the nucleation layer 61 on them as well. The material of the nucleation layer 61 is selected to be a compatible match with oxygen atoms which have been removed from the silicon wafer during the pre-cleaning step.

As is known in the art, different elements more easily attach to and bond with certain elements more than others. Indeed, it is well known that certain layers provide a high quality nucleation substrate that provides multiple nucleation sites for the easy formation of a particular type of layer which will be stably coupled to such a substrate once it is formed. According to the present invention, such a nucleation layer 61 is formed on the inside surface of the bell jar. The material of the nucleation layer 61 is selected to have a very high affinity to the atoms which are expected to be dislodged from the silicon wafer during the pre-clean step. The atoms, upon being vaporized will begin to form a seed layer on the interior surface 42 of the bell jar 40. Because of the high affinity to the nucleation layer 61, the atoms will stick strongly to the layer and will not easily flake off during later processing steps or when another wafer is put into or removed from the pre-clean chamber 23.

In one embodiment of the present invention, the nucleation layer 61 is a zirconium oxide (ZrO₂). In another embodiment, the nucleation layer 61 is an yttrium oxide (YO₂, Y₂O₃). In yet another embodiment of the invention, the nucleation layer 61 is a blend of zirconium oxide (ZrO₂) and yttrium oxide (Y₂O₃) or, alternatively a blend of zirconium oxide and aluminum oxide (Al₂O₃). In further embodiments of the present invention, the element from the periodic chart group IVB is combined with another element from group VIA to form a compound that becomes the nucleation layer 61. Alternatively, elements in column IIA and IIIB may also be combined with one or more elements from group VA and VIA in order to provide a stable nucleation layer 61 on the inner surface of the bell jar, depending on the material.

In a preferred embodiment, the material which is to be adhered to the nucleation layer 61 is oxygen. The materials available for the nucleation layer 61 are an oxide or some other compound or combination with oxygen. Preferably, since the material to be the nucleation layer 61 is an oxide of an element selected from columns IIIB or IVB from the period chart. The coating of this nucleation layer 61 which contains an oxide is applied to the inner surface 42 of the quartz bell jar 40 acts like a particle grabber. The coating itself is of selected thickness such that it will form many nucleation sites. It may be in the range of 0.1 to 500 microns thick, preferably about 150 microns in thickness. During the pre-cleaning process, the oxygen atoms are bombarded as they are removed from the silicon wafer. The oxygen atoms come in contact with the interior surface 42 of the bell jar and strongly adhere to the nucleation layer 61 at nucleation sites. They begin to form an oxide layer on the interior surface of the bell jar itself. The formation adherence of the oxide layer is of such strength on the bell jar surface itself that the oxygen atoms strongly adhere to the bell jar and do not flake off even though the bell jar may have numerous wafers enter or leave it during subsequent semiconductor processing.

A preferred method of applying the nucleation layer 61 is as follows. The interior surface 42 of the bell jar is prepared for the application of the nucleation layer 61. In one embodiment, the surface 42 is subjected to bead blasting. The bead blasting serves to remove any grit or particles from the surface 42 of the quartz or glass and to roughen up the surface for good adherence of the nucleation layer 61. During the bead blasting, the quartz bell jar 42 may be kept in the presence of argon gas or some other inert or regular atmosphere condition. The bead blasting provides a roughened surface to ensure good adherence of the nucleation layer 61 itself. Other cleaning techniques may be used to clean the quartz, such as a chemical scrub or other etch.

The nucleation layer 61 is preferably deposited to a thickness of approximately 0.1-500 microns, preferably about 100-200 microns. The deposition temperature will be selected based on the material being selected. For a zirconium oxide, deposition can be at room temperature. The ZrO₂ is deposited by a plasma torch. A powder ZrO₂ or mixture of ZrO₂ is provided at the inlet of a nozzle and current is passed through the nozzle to place the ZrO₂ into an ionic state. A plasma jet is formed of the ZrO₂ and it is sprayed onto the interior surface 42 of the bell jar 40. One acceptable example of how to achieve this is shown in the '045 patent. It may be applied by other techniques, such as sputter deposition from a solid target having Zirconium. The formation and deposition of the nucleation layer 61 onto bell jar 40 preferably takes place in the presence of oxygen gas, such as standard atmosphere, so that sufficient oxygen is always present to form a stable compound for the nucleation layer 61.

After the nucleation layer 61 is deposited on the bell jar 40, the entire combination of the bell jar and nucleation layer 61 are slow baked in order to remove all gases, vapor and moisture. The bake is preferably done for approximately twenty-four hours at a temperature in the range of 75-100° in a pure nitrogen atmosphere. The use of a pure nitrogen atmosphere is helpful to ensure that the nucleation layer 61 completely outgases and is sufficiently free of all impurities prior to use.

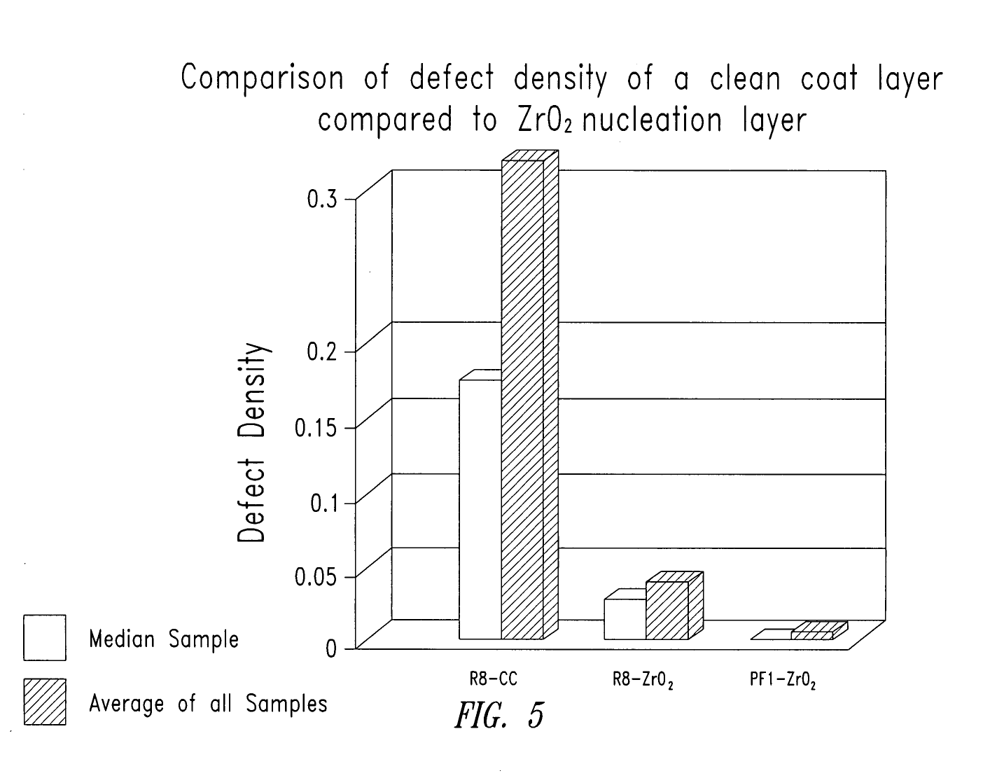

FIG. 5 shows the improved results which have been obtained in experiments conducted using the present invention. In FIG. 5, defect density for the prior art is compared to the defect density in experiments conducted using nucleation layer 61 of the present invention. The prior art, shown as R8-CC which stands for fab R8 having a prior art clean coat on the bell jar 40 was compared in the very same fab to a nucleation layer 61 composed of zirconium oxide on the bell jar 40. As can be seen, the prior art clean coat had median defect densities in the range of 0.15-0.2. The average defect density was 0.31. On the other hand, samples of wafer processed using the present invention in the very same fab had a medium defect density of 0.03, and an average defect density of 0.04. In another semiconductor processing facility, labeled PF1, the bell jar having a zirconium oxide coating had defect densities of less than 0.01.

An explanation of the way in which defects occur and how the invention prevents the defects is helpful in understanding the operation and context of the present invention. In the pre-clean chamber, thin layers of material, such as oxide or other layers are removed from the wafer. The layer is removed by plasma etching at an acceptable RF power. Such plasma etching is well known in the art. The particles which are removed, such as the oxide, may temporarily stick to the wall of the bell jar. Sometime later, when another wafer is being introduced into the pre-clean chamber, the oxide particles fall from the bell jar and attach to the semiconductor wafer which has just been cleaned. Often, the location for attachment or the site is sufficient that it causes a defect in the wafer so that one or more chips on the wafer become non-operative. The bell jar of the pre-clean chamber can only be used while it is sufficiently clean to keep from contaminating wafers as they enter and leave the pre-clean chamber 22. As it continues to be used, impurities build up on the interior surface 42 and, when they are sufficiently thick, begin to dislodge, resulting in possible contamination. The time over which a bell jar is used can be measured by the kilowatt-hours it is used. Typically, a bell jar will be used for a time period and power combination of about 5 to 6 kilowatt hours a week. In the prior art, after 2 to 3 weeks, the bell jar is so contaminated, it must be removed and replaced. This is an expensive and time consuming operation. While the bell jar 40 is being cleaned, the facility 10 cannot be used, which results in down time and expensive loss of throughput. In current systems, it is common to have to replace the bell jar after 3 to 5 weeks of use. If used for this period of time, the pre-clean chamber has been sufficiently contaminated with material that new wafers entering or exiting the pre-clean chamber are contaminated and the defects are sufficiently high that overall, the chamber 23 is reducing yields. This may be due to flaking of the shield 54, the oxide layer on the bell jar 46 flaking off onto the semiconductor wafer, residual tungsten falling onto the wafer, or other defects.

A pre-clean chamber which has a nucleation layer 61 according to the present invention applied thereon has considerably longer life than was possible for pre-clean chambers in the prior art. The same bell jar 40 may be used for 4 to 6 months without needing to be removed and cleaned. Once removed, the bell jar 40 of the invention can be cleaned of impurities which have affixed in a nucleation layer 61 and the same bell jar used again. The cost to clean, refurbish a bell jar having the nucleation layer 61 of the present invention may be in the range of $2000 as compared to the prior art cost of cleaning and replacing a bell jar being in the range of $7000. This, coupled with the low defects which occur from use of the nucleation layer 61 of the present invention provides substantially advantages over the prior art.

Once the bell jar 40 is removed for cleaning, the oxide layer that has formed on the nucleation layer 61 is removed by any acceptable technique, such as wet etching, a chemical wash, or other removal method. The ZrO₂ layer, being a very tough layer, is usually not affected by removal of the oxide layer when the bell jar 40 is cleaned. Thus, after the oxide layer is cleaned, the same bell jar, with the prior nucleation layer 61, is reused for several more months. The bell jar 40 can be removed, cleaned, and reused many times. If the ZrO₂ layer becomes thin or has a hole, a new ZrO₂ layer can simply be applied on top of the existing layer.

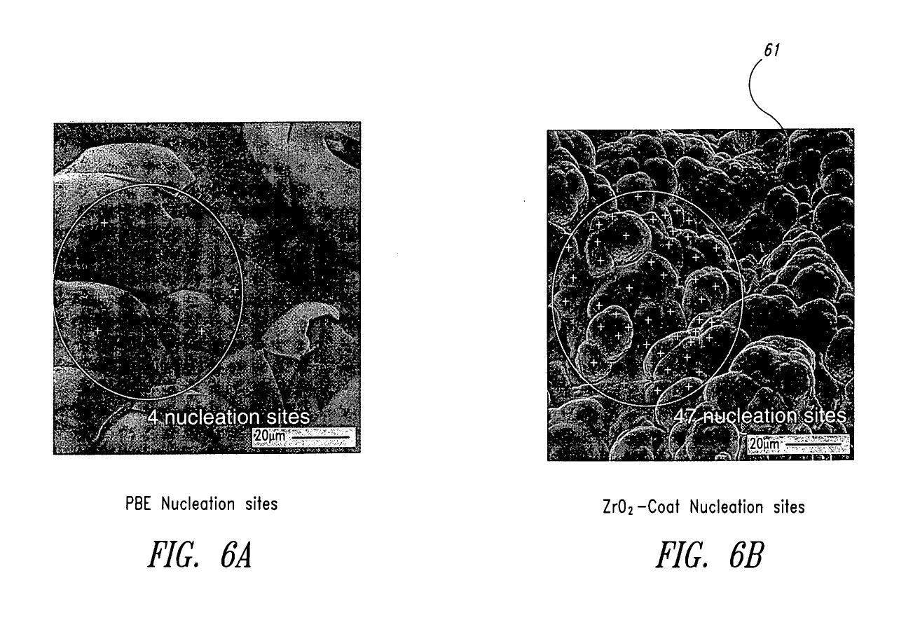

Examples of the present invention nucleation layer 61 as compared to the prior art layer are illustrated in FIGS. 6A and 6B. In this embodiment, the prior art of a TWAS (twin wire arc spray) or PBE (post blast etch) coated surface is shown at a high magnification. TWAS is one well-known prior art coating technique which relies on roughness or other structures rather than a nucleation layer. As can be seen in FIG. 6A, having a PBE layer, there are approximately 4 nucleation sites for the growth of an oxide layer in a circle having a radius of 30 microns. Compared to the present invention, the same area has approximately 47-50 nucleation sites for the attachment of an oxide growth layer. Namely, the nucleation layer 61 of the present invention has approximately ten times more nucleation sites than was available in the prior art. The present invention has about 100 nucleation sites for every 500 to 600 square microns; the prior art has less than 10 nucleation sites for every 7000 square microns.

The present invention also has significant advantages as used on the shield 54, the pedestal 44 and various gaskets and adaptors. One of the problems of the prior art is that the shield and/or the pedestal, are typically made of different materials than the quartz of the bell jar materials from which the pedestal and shield are made. They may be made of aluminum or some other metal, a rubber, a high density plastic, or the like. According to one embodiment of the present invention, all components inside the pre-clean chamber are coated with a nucleation layer 61 including the shield 54, the pedestal 44, the exposed portions of the wafer check 48. Even in some embodiments, exposed portions of the adapter 62 and the gas trench cover and gaskets may also be coated with the nucleation layer 61. Of course, it is not necessary to coat those portions with a nucleation layer 61 which are not exposed to the atmosphere inside of the interior of the chamber 26. Also, materials are not coated with the nucleation layer 61 if it would interfere with their intended purpose in sealing the bell jar.

Typically, the shield 54 will be composed of aluminum. The shield is normally used to prevent the etched oxide from depositing on undesirable locations within the chamber, such as the interior chamber walls 43. Since it is very difficult to clean these interior chamber walls as well as costly, it is preferred to keep these interior chamber walls as clean as possible for as long as the cleanliness can be maintained. The aluminum shield 54 assists in collecting the particles which are removed from the wafer 50 and growing them onto the shield 54 where they firmly adhere. The nucleation layer 61 is formed on the shield and other components besides on the bell jar to increase the range and different types of particles which may be adhered to the various surfaces.

In one embodiment, the nucleation layer 61 on the shield 54 is a different composition than on the bell jar 40. Since the shield 54 is composed of aluminum, a nucleation layer of aluminum oxide, Al₂O₃ is preferred. This will provide strong adherence of the layer 61 to the shield and also to the oxygen in the vapor. In the same chamber 23, the bell jar, being quartz, has a nucleation layer of Y₂O₃ or ZrO₂, which are closer to glasses, for forming a strong bond to the quartz and a strong bond between the quartz and the grown oxide layer. Thus, the nucleation layer is selected to be a combination that will provide a strong adherence to the surface it is being deposited onto and a strong adherence to the material to be cleaned or etched form the silicon wafer.

As a further example, the nucleation layer may be a titanium nitride if it is being deposited onto an aluminum or titanium member inside the chamber 23 and the material being cleaned in a nitride layer. Thus, some components inside the chamber 23 may have an aluminum nitride or titanium nitride layer to attract and bond with the free nitrogen, while other components in the same chamber may be coated with an oxide based nucleation layer, such as ZrO₂.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A plasma chamber comprising:
an upper insulating member positioned as a lid of the plasma chamber, an inside surface of the upper insulating member forming a top surface of the interior of the plasma chamber; and
a nucleation layer affixed to the insulating member, the nucleation layer having a plurality of nucleation sites that will bond with a material being etched in the plasma chamber.

2. The plasma chamber of claim 1, further including:
a semiconductor wafer holder within the plasma chamber;
a shield member positioned at a lower region of the plasma chamber, the shield member being positioned adjacent to the semiconductor wafer holder; and
a nucleation layer affixed to the shield member.

3. The plasma chamber of claim 2 wherein the nucleation layer on the shield member has the same chemical composition as the nucleation layer on the upper insulating member.

4. The plasma chamber of claim 1 wherein the number of nucleation sites is in excess of 100 sites per 500 square microns.

5. The plasma chamber of claim 1 wherein the nucleation layer consists of ZrO₂.

6. The plasma chamber of claim 1 wherein the nucleation layer contains the compound ZrO₂.

7. The plasma chamber of claim 1 wherein the nucleation layer contains a compound of Yttrium and oxygen.

8. The plasma chamber of claim 7 wherein the compound of yttrium and oxygen is Y₂O₃.

9. A chamber comprising:
a lid having an inside surface and an outside surface, the lid being composed of an electrically insulating material;
a wafer support chuck;
an interior chamber wall;
an oxygen nucleation layer bonded to the inside surface of the lid, the oxygen nucleation layer having a plurality of nucleation sites for oxygen to bond with nucleation layer and thus to be bonded to the inside surface of the lid.

10. The chamber according to claim 9 further including a nucleation layer bonded to the interior chamber wall.

11. A method comprising:
cleaning an inside surface of a bell jar lid;
depositing an oxygen nucleation layer on an inside surface of the bell jar lid;
baking the nucleation layer and bell jar lid for a period of time selected to be sufficient to remove substantially all water vapor and moisture from the nucleation layer and in an atmosphere that is selected to assist in the removal of water vapor and moisture from the nucleation layer.

12. The method according to claim 11 wherein the bake time is select to ensure that substantially all gases are removed from the nucleation layer.

13. The method according to claim 12 wherein the baking occurs in a pure nitrogen atmosphere for a period of time in excess of 20 hours at a temperature in excess of 75° C.

14. The method according to claim 11 wherein the step of cleaning the inside surface of the bell jar includes:
bead blasting the inside surface of the bell jar in a selected gas atmosphere.

15. The method according to claim 14 wherein the selected gas is argon.

16. The method according to claim 11 wherein depositing an oxide nucleation layer includes:
depositing ZrO₂ on an inside surface of the bell jar.

17. The method according to claim 16 wherein the deposition takes place in an atmosphere that includes oxygen.

18. The method according to claim 11 wherein depositing an oxide nucleation layer includes:
depositing Y₂O₃ on an inside surface of the bell jar.
